(19) United States
(12) Patent Application Publication
(10) Pub. No.: US 2022/0238557 A1
(43) Pub. Date: Jul. 28, 2022

(54) ARRAY SUBSTRATE, METHOD FOR FORMING THE SAME AND DISPLAY DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Zhuo XU, Beijing (CN); Haigang YANG, Beijing (CN); Jungho PARK, Beijing (CN); Xiaofeng MA, Beijing (CN)

(21) Appl. No.: 17/433,531

(22) PCT Filed: Feb. 2, 2021
(86) PCT No.: PCT/CN2021/074860

§ 371 Date: Aug. 24, 2021

(30) Foreign Application Priority Data
Mar. 25, 2020 (CN) 202010218324.8

(51) Int. Cl. H01L 27/12

(52) U.S. Cl. CPC H01L 27/124; G02F 1/13394; H01L 27/1259

(57) ABSTRACT

An array substrate, a method for forming the array substrate and a display device are provided, each transistor structure in the array substrate includes: a gate pattern, an active pattern and two electrode patterns. The two electrode patterns correspond to two electrode contact regions respectively. Each electrode pattern includes a first electrode sub-pattern and a second electrode sub-pattern coupled to each other, an orthographic projection of the first electrode sub-pattern onto the base substrate and that of a corresponding electrode contact region onto the base substrate form a first overlapping region, the second electrode sub-pattern covers a part of a first boundary of the gate pattern, and an angle between an extension direction of an orthographic projection of the second electrode sub-pattern onto the base substrate and an extension direction of an orthographic projection of the part of the first boundary onto the base substrate is less than 90 degrees.

### CROSS-REFERENCE TO RELATED APPLICATIONS

This application is the U.S. national phase of PCT Application No. PCT/CN2021/074860 filed on Feb. 2, 2021 which claims priority to Chinese Patent Application No. 202010218324.8 filed on Mar. 25, 2020, the disclosures of which are incorporated in their entirety by reference herein.

### TECHNICAL FIELD

The present disclosure relates to the field of display technology, in particular to an array substrate, a method for forming the array substrate and a display device.

### BACKGROUND

As a resolution of a display product increases, a size of each transistor for driving the display product to display in the display product is getting smaller and smaller. Although it is able to reduce a load and increase a pixel aperture ratio of the display product by reducing the size of the transistor, when forming the transistor, a part of film layers in the transistor breaks easily at a step position due to a same etching time, thereby leading to reducing the yield of the display product.

### SUMMARY

An objective of the present disclosure is to provide an array substrate, a method for forming the array substrate and a display device.

In order to achieve the above objectives, the present disclosure provides the following technical solutions.

In a first aspect, an array substrate is provided, including: a base substrate and a plurality of transistor structures arranged on the base substrate. Each transistor structure includes: a gate pattern, an active pattern located on a side of the gate pattern away from the base substrate, the active pattern including two electrode contact regions spaced apart from each other and a channel region located between the two electrode contact regions; and two electrode patterns located on a side of the active pattern away from the base substrate and corresponding to the two electrode contact regions respectively. Each electrode pattern includes a first electrode sub-pattern and a second electrode sub-pattern coupled to each other, an orthographic projection of the first electrode sub-pattern onto the base substrate and an orthographic projection of a corresponding electrode contact region onto the base substrate form a first overlapping region, the first electrode sub-pattern is coupled to the active pattern located in the corresponding electrode contact region in the first overlapping region, the second electrode sub-pattern covers a part of a first boundary of the gate pattern, and an angle between an extension direction of an orthographic projection of the second electrode sub-pattern onto the base substrate and an extension direction of an orthographic projection of the part of the first boundary onto the base substrate is less than 90 degrees.

Optionally, an orthographic projection of the active pattern onto the base substrate is covered by an orthographic projection of the gate pattern onto the base substrate, the second electrode sub-pattern covers a part of a second boundary of the active pattern, and an angle between the extension direction of the orthographic projection of the second electrode sub-pattern onto the base substrate and an extension direction of an orthographic projection of the part of the second boundary onto the base substrate is less than 90 degrees.

Optionally, the array substrate further includes: a plurality of gate lines, a plurality of transistors forming a plurality of transistor rows arranged sequentially along a first direction, each transistor row including the plurality of the transistor structures spaced apart from each other along a second direction, the gate lines corresponding to the transistor rows respectively, and each gate line being coupled to gate patterns of the transistor structures in a corresponding transistor row; and a barrier wall structure, an orthographic projection of at least a part of the barrier wall structure onto the base substrate being located between orthographic projections of two adjacent gate patterns coupled to a same gate line onto the base substrate.

Optionally, an orthographic projection of each gate pattern onto the base substrate is located between orthographic projections of two adjacent barrier wall structures onto the base substrate.

Optionally, the two electrode patterns include an input electrode pattern and an output electrode pattern, the output electrode pattern includes the first electrode sub-pattern, the second electrode sub-pattern and a third electrode sub-pattern coupled to each other sequentially, the second electrode sub-pattern is located between the first electrode sub-pattern and the third electrode sub-pattern, and in the transistor structure where the third electrode sub-pattern is located, the third electrode sub-pattern is located on a side of the first electrode sub-pattern away from the input electrode pattern; and the barrier wall structure includes a first barrier wall portion extending from the third electrode sub-pattern, and an orthographic projection of the first barrier wall portion onto the base substrate is located between the orthographic projections of the two adjacent gate patterns coupled to the same gate line onto the base substrate.

Optionally, the barrier wall structure further includes a second barrier wall portion extending from the third electrode sub-pattern, an orthographic projection of the third electrode sub-pattern onto the base substrate, the orthographic projection of the first barrier wall portion extending from the third electrode sub-pattern onto the base substrate and an orthographic projection of the second barrier wall portion extending from the third electrode sub-pattern onto the base substrate are all located between orthographic projections of adjacent gate patterns in a same group onto the base substrate, the orthographic projection of the first barrier wall portion onto the base substrate is located between the orthographic projection of the second barrier wall portion onto the base substrate and an orthographic projection of a first gate pattern of the adjacent gate patterns in the same group onto the base substrate, and the orthographic projection of the second barrier wall portion onto the base substrate is located between the orthographic projection of the first barrier wall portion onto the base substrate and an orthographic projection of a second gate pattern of the adjacent gate patterns in the same group onto the base substrate.

Optionally, the first barrier wall portion includes a first barrier wall pattern and a second barrier wall pattern that extend in different directions, the first barrier wall pattern is coupled to the second barrier wall pattern at a coupling position where a first angle facing the first gate pattern is formed, and the first angle is less than 180 degrees; and/or, the second barrier wall portion includes a third barrier wall pattern and a fourth barrier wall pattern that extend in different directions, the third barrier wall pattern is coupled to the fourth barrier wall pattern at a coupling position where a second angle facing the second gate pattern is formed, and the second angle is less than 180 degrees.

Optionally, the barrier wall structure is arranged at a same layer and made of a same material as the two electrode patterns.

Optionally, the two electrode patterns include an input electrode pattern and an output electrode pattern; the plurality of transistor structures are arranged in an array form, and form a plurality of transistor rows and a plurality of transistor columns; the array substrate further includes a plurality of gate lines and a plurality of data lines crossing each other, the gate lines correspond to the transistor rows respectively, each gate line is coupled to gate patterns of the transistor structures in a corresponding transistor row, the data lines correspond to the transistor columns respectively, and each data line is coupled to second electrode sub-patterns of input electrode patterns of the transistor structures in a corresponding transistor column.

In a second aspect, a display device is provided, including the above-mentioned array substrate.

Optionally, the display device further includes a color filter substrate disposed opposite to the array substrate, the color filter substrate includes a plurality of spacers corresponding to at least part of gate patterns in the array substrate respectively, an orthographic projection of a top surface of each spacer close to the array substrate onto the base substrate of the array substrate overlaps an orthographic projection of the corresponding gate pattern onto the base substrate, and an orthographic projection of a barrier wall structure in the array substrate onto the base substrate is located at the periphery of the orthographic projection of the top surface onto the base substrate.

Optionally, the color filter substrate further includes a black matrix layer, and an orthographic projection of the black matrix layer onto the base substrate of the array substrate covers an orthographic projection of a barrier wall structure in the array substrate onto the base substrate.

In a third aspect, a method for forming the above-mentioned array substrate is provided, including: forming a plurality of transistor structures arranged on a base substrate. Each transistor structure includes: a gate pattern, an active pattern located on a side of the gate pattern away from the base substrate, the active pattern including two electrode contact regions spaced apart from each other and a channel region located between the two electrode contact regions; and two electrode patterns located on a side of the active pattern away from the base substrate and corresponding to the two electrode contact regions respectively. Each electrode pattern includes a first electrode sub-pattern and a second electrode sub-pattern coupled to each other, an orthographic projection of the first electrode sub-pattern onto the base substrate and an orthographic projection of a corresponding electrode contact region onto the base substrate form a first overlapping region, the first electrode sub-pattern is coupled to the active pattern located in the corresponding electrode contact region in the first overlapping region, the second electrode sub-pattern covers a part of a first boundary of the gate pattern, and an angle between an extension direction of an orthographic projection of the second electrode sub-pattern onto the base substrate and an extension direction of an orthographic projection of the part of the first boundary onto the base substrate is less than 90 degrees.

Optionally, the forming the two electrode patterns includes: forming a first electrode sub-pattern and a second electrode sub-pattern in each electrode pattern and a barrier wall structure in the array substrate simultaneously through one patterning process.

### BRIEF DESCRIPTION OF THE DRAWINGS

The following drawings are provided to facilitate the understanding of the present disclosure, and constitute a portion of the present disclosure. These drawings and the following embodiments are for illustrative purposes only, but shall not be construed as limiting the present disclosure. In these drawings,

FIG. 1 is a schematic diagram of a transistor structure in an array substrate according to an embodiment of the present disclosure;

FIG. 2 is another schematic diagram of the transistor structure in the array substrate according to an embodiment of the present disclosure;

FIG. 3 is yet another schematic diagram of the transistor structure in the array substrate according to an embodiment of the present disclosure;

FIG. 4 is a schematic diagram of the transistor structure and a barrier wall structure in the array substrate according to an embodiment of the present disclosure;

FIG. 5 is another schematic diagram of the transistor structure and the barrier wall structure in the array substrate according to an embodiment of the present disclosure;

FIG. 6 is a schematic diagram of the array substrate according to an embodiment of the present disclosure;

FIG. 7 is another schematic diagram of the array substrate according to an embodiment of the present disclosure; and

FIG. 8 is a sectional view of the array substrate in FIG. 7 along line A1A2.

### DETAILED DESCRIPTION

An array substrate, a method for forming the array substrate and a display device of the embodiments of the present disclosure will be described in detail hereinafter in conjunction with the accompanying drawings.

In order to solve a problem that a part of film layers in the transistor breaks easily at a step position, leading to reducing the yield of the display product in a better manner, a line width of each of the part of the film layers in the transistor at the step position may be considered to be increased. Referring to FIG. 1, line widths (as shown in dashed boxes A and B in FIG. 1) of an input electrode 13 and an output electrode 12 in the transistor are increased at steps formed by a gate pattern 11 and an active pattern 14. For example, the line widths of the input electrode 13 and the output electrode 12 may each be increased from 4.795206 μm to 5.3 μm.

Although it is able to reduce the probability of a step breakage by using the above-mentioned method, an overlapping capacitance may be increased while increasing the line widths, so as to increase a load of the transistor, decrease a charging rate of the transistor, and increase a logic power consumption. In addition, the higher a resolution of the display product, the worse the above effects. Thus, the above method may be not suitable for a high-resolution display product.

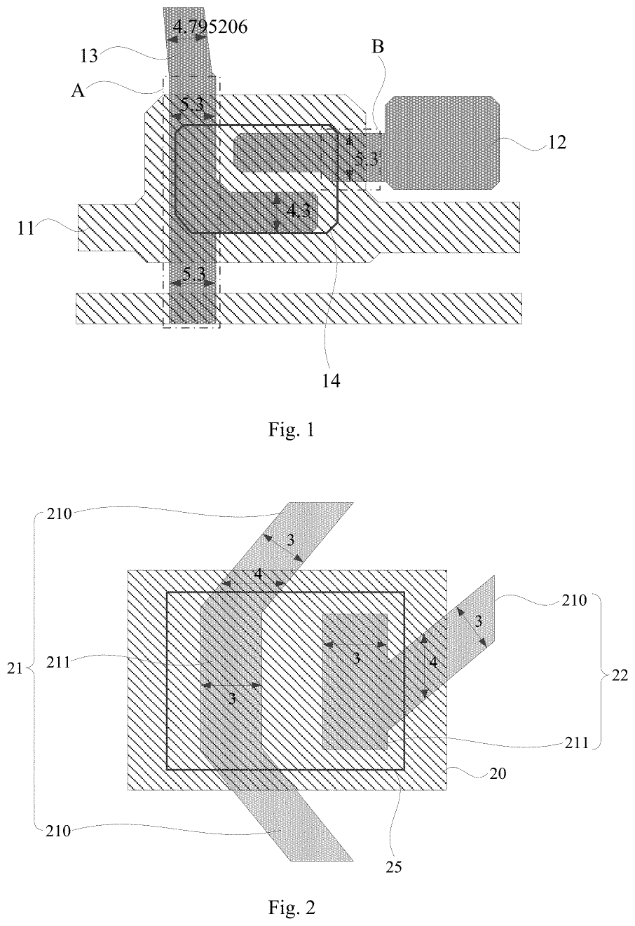

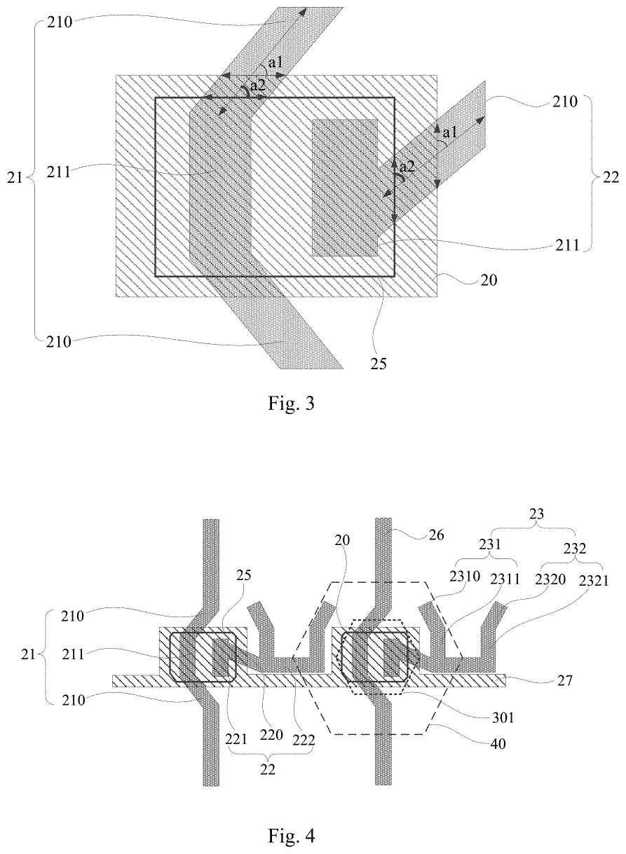

Referring to FIG. 2 and FIG. 3, an array substrate is provided, including: a base substrate and a plurality of transistor structures arranged on the base substrate. Each transistor structure includes: a gate pattern 20, an active pattern 25 located on a side of the gate pattern 20 away from the base substrate, the active pattern 25 including two electrode contact regions spaced apart from each other and a channel region located between the two electrode contact regions; and two electrode patterns located on a side of the active pattern 25 away from the base substrate and corresponding to the two electrode contact regions respectively. Each electrode pattern includes a first electrode sub-pattern 211 and a second electrode sub-pattern 210 coupled to each other, an orthographic projection of the first electrode sub-pattern 211 onto the base substrate and an orthographic projection of a corresponding electrode contact region onto the base substrate form a first overlapping region, the first electrode sub-pattern 211 is coupled to the active pattern located in the corresponding electrode contact region in the first overlapping region, the second electrode sub-pattern 210 covers a part of a first boundary of the gate pattern 20, and an angle between an extension direction of an orthographic projection of the second electrode sub-pattern 210 onto the base substrate and an extension direction of an orthographic projection of the part of the first boundary onto the base substrate is less than 90 degrees.

To be specific, the array substrate includes a first gate metal layer, an insulation layer, an active layer, an insulation layer and a source-drain metal layer that are sequentially laminated one on another in a direction away from the base substrate. The gate pattern 20 in the transistor structure may be formed by using the first gate metal layer, the active pattern 25 may be formed by using the active layer, the two electrode patterns may be formed by using the source-drain metal layer, and the transistor structure may be formed as a thin film transistor having a bottom gate structure.

The active pattern 25 has various layout modes. For example, an orthographic projection of the active pattern 25 onto the base substrate is within an orthographic projection of the gate pattern 20 onto the base substrate. Further, the active pattern 25 includes the two electrode contact regions spaced apart from each other and the channel region located between the two electrode contact regions. The channel region may be specifically I-shaped, L-shaped, U-shaped or another shape.

The two electrode patterns may be used as an input electrode pattern 21 and an output electrode pattern 22 respectively of the transistor structure, and correspond to the two electrode contact regions respectively. Each electrode pattern includes the first electrode sub-pattern 211 and the second electrode sub-pattern 210 coupled to each other, the orthographic projection of the first electrode sub-pattern 211 onto the base substrate and the orthographic projection of the corresponding electrode contact region onto the base substrate form a first overlapping region, a via-hole may be provided in the first overlapping region, and the first electrode sub-pattern 211 is coupled to the active pattern in the corresponding electrode contact region through the via-hole. Further, the orthographic projection of the first electrode sub-pattern 211 onto the base substrate may be, but not limited to, within the orthographic projection of the corresponding electrode contact region onto the base substrate.

There are various specific structures for the second electrode sub-pattern 210. For example, in a direction parallel to the base substrate, the second electrode sub-pattern 210 may extend from the periphery of the gate pattern 20 to the corresponding electrode contact region, and be coupled to the first electrode sub-pattern 211. The second electrode sub-pattern 210 may cover a part of the first boundary of the gate pattern 20, that is, the second electrode sub-pattern 210 extends across a step generated by the gate pattern 20 at the part of the first boundary.

As shown in FIG. 3, when the angle a1 between the extension direction of the orthographic projection of the second electrode sub-pattern 210 onto the base substrate and the extension direction of the orthographic projection of the part of the first boundary onto the base substrate is less than 90 degrees, it is able to increase a step width of the second electrode sub-pattern 210 at the part of the first boundary. It should be appreciated that, the step width is referred to as a width of a step portion of the second electrode sub-pattern 210 at the part of the first boundary along an extension direction of the part of the first boundary.

For example, as shown in FIGS. 2 and 3, the step width of the second electrode sub-pattern 210 is 4 μm, and a width of the second electrode sub-pattern 210 in a direction perpendicular to an extension direction thereof is 3 μm. Further, when a1 is 45 degrees, the step width of the second electrode sub-pattern 210 may reach 4.25 μm. Therefore, when setting the second electrode sub-pattern 210 by using the above-mentioned mode, it is able to avoid the increase of the overlapping capacitance between the second electrode sub-pattern 210 and the gate pattern 20 while increasing the step width.

It should be appreciated that, an extension direction of the first electrode sub-pattern 211 and an extension direction of the second electrode sub-pattern 210, as well as an angle formed between the first electrode sub-pattern 211 and the second electrode sub-pattern 210 may be set according to actual needs. For example, as shown in FIG. 4, the extension direction of the first electrode sub-pattern 211 is the same as an extension direction of a data line 26 in the array substrate, and both the extension direction of the second electrode sub-pattern 210 and the extension direction of the data line 26 cross an extension direction of a gate line 27 in the array substrate. For example, an angle between the first electrode sub-pattern 211 and the second electrode sub-pattern 210 is less than 90 degrees.

According to the specific structure of the array substrate, in the array substrate of the embodiments of the present disclosure, the second electrode sub-pattern 210 covers a part of the first boundary of the gate pattern 20, and the angle between the extension direction of the orthographic projection of the second electrode sub-pattern 210 onto the base substrate and the extension direction of the orthographic projection of the part of the first boundary onto the base substrate is less than 90 degrees. Thus, the second electrode sub-pattern 210 may obliquely climb the step generated by the gate pattern 20 at the part of the first boundary, so as to change a step angle of the second electrode sub-pattern 210, and increase the step width of the second electrode sub-pattern 210 without increasing the width of the second electrode sub-pattern 210 in the direction perpendicular to the extension direction thereof, thereby to reduce the probability of the second electrode sub-pattern 210 breaking at the step while avoiding such problems as the decrease of the charging rate of the transistor and the increase of the logic power consumption. In addition, the array substrate of the embodiments of the present disclosure may be applied to the high-resolution display product.

As shown in FIG. 2 and FIG. 3, in some embodiments, an orthographic projection of the active pattern 25 onto the base substrate is covered by an orthographic projection of the gate pattern 20 onto the base substrate, the second electrode sub-pattern 210 covers a part of a second boundary of the active pattern 25, and an angle between the extension direction of the orthographic projection of the second electrode sub-pattern 210 onto the base substrate and an extension direction of an orthographic projection of the part of the second boundary onto the base substrate is less than 90 degrees.

To be specific, a step may be generated at the boundary of the active pattern 25, when the second electrode sub-pattern 210 covers a part of the second boundary of the active pattern 25, the angle a2 between the extension direction of the orthographic projection of the second electrode sub-pattern 210 onto the base substrate and the extension direction of the orthographic projection of the part of the second boundary onto the base substrate is less than 90 degrees, it is able to increase a step width of the second electrode sub-pattern 210 at the part of the second boundary. It should be appreciated that, the step width is referred to as a width of a step portion of the second electrode sub-pattern 210 at the part of the second boundary along an extension direction of the part of the second boundary.

In the array substrate of the embodiments of the present disclosure, the second electrode sub-pattern 210 covers a part of the second boundary of the active pattern 25, and the angle between the extension direction of the orthographic projection of the second electrode sub-pattern 210 onto the base substrate and the extension direction of the orthographic projection of the part of the second boundary onto the base substrate is less than 90 degrees. Thus, it is able to change a step angle of the second electrode sub-pattern 210 at the part of the second boundary, and increase the step width of the second electrode sub-pattern 210 without increasing the width of the second electrode sub-pattern 210 in the direction perpendicular to the extension direction thereof, thereby to reduce the probability of the second electrode sub-pattern 210 breaking at the step while avoiding such problems as the decrease of the charging rate of the transistor and the increase of the logic power consumption. In addition, the array substrate of the embodiments of the present disclosure may be applied to the high-resolution display product.

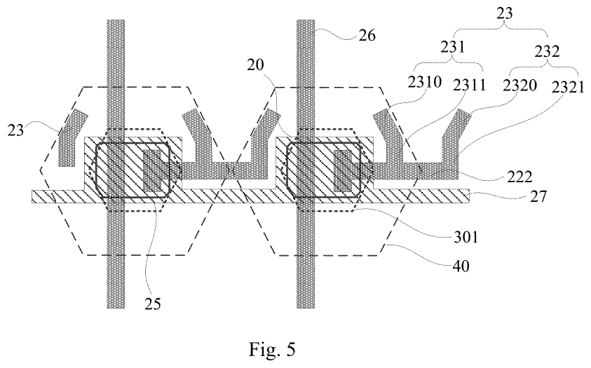

As shown in FIGS. 4 and 5, in some embodiments, the array substrate further includes: a plurality of gate lines 27, a plurality of transistors forming a plurality of transistor rows arranged sequentially along a first direction, each transistor row including the plurality of the transistor structures spaced apart from each other along a second direction, the gate lines corresponding to the transistor rows respectively, and each gate line being coupled to gate patterns of the transistor structures in a corresponding transistor row; and a barrier wall structure 23, an orthographic projection of at least a part of the barrier wall structure 23 onto the base substrate being located between orthographic projections of two adjacent gate patterns 20 coupled to a same gate line 27 onto the base substrate.

To be specific, the first direction may be, but not limited to, an X direction, and the second direction may be, but not limited to, a Y direction. The gate line is used to provide a scan signal for each transistor structure coupled to the gate line.

For example, when the array substrate is applied to a liquid crystal display device, the display device further includes a color filter substrate disposed opposite to the array substrate, a plurality of spacers is arranged between the color filter substrate and the array substrate, and corresponds to at least part of the transistor structures in the array substrate respectively, each spacer is located on a side of a corresponding transistor structure away from the base substrate, and may abut against the corresponding transistor structure and the color filter substrate. For example, an orthographic projection of each spacer onto the base substrate may overlap the orthographic projection of the gate pattern 20 in the corresponding transistor structure onto the base substrate.

When the orthographic projection of the barrier wall structure 23 onto the base substrate is located between the orthographic projections of two adjacent gate patterns 20 coupled to the same gate line 27 onto the base substrate, it is able for the barrier wall structure 23 to compensate for a step difference generated by the gate pattern 20, so as to provide a relatively flat surface of the array substrate that is in contact with the spacer. Thus, each spacer between the transistor structure and the color filter substrate is not easy to slide toward the periphery of the gate pattern 20, so as to effectively reduce the probability of scratching an alignment layer due to the sliding of the spacer, and improve the yield of the display product.

In addition, when the orthographic projection of the barrier wall structure 23 onto the base substrate is located between the orthographic projections of two adjacent gate patterns 20 coupled to the same gate line onto the base substrate, there is no overlapping region between the barrier wall structure 23 and the gate pattern 20 in a direction perpendicular to the base substrate, so as to avoid an additional load.

In some embodiments, an orthographic projection of each gate pattern 20 onto the base substrate is located between orthographic projections of two adjacent barrier wall structures 23 onto the base substrate. Thus, it is able to provide the barrier wall structures 23 on both sides of each gate pattern 20, so as to effectively reduce the probability of scratching the alignment layer due to the sliding of the spacer, and improve the yield of the display product.

As shown in FIGS. 4 and 5, in some embodiments, the two electrode patterns include an input electrode pattern 21 and an output electrode pattern 22, the output electrode pattern 22 includes the first electrode sub-pattern 221, the second electrode sub-pattern 220 and a third electrode sub-pattern 222 coupled to each other sequentially, the second electrode sub-pattern 220 is located between the first electrode sub-pattern 221 and the third electrode sub-pattern 222, and in the transistor structure where the third electrode sub-pattern 222 is located, the third electrode sub-pattern 222 is located on a side of the first electrode sub-pattern 221 away from the input electrode pattern 21; and the barrier wall structure 23 includes a first barrier wall portion 231 extending from the third electrode sub-pattern 222, and an orthographic projection of the first barrier wall portion 231 onto the base substrate is located between the orthographic projections of the two adjacent gate patterns 20 coupled to the same gate line 27 onto the base substrate.

To be specific, the two electrode patterns may include the input electrode pattern 21 and the output electrode pattern 22. For example, the input electrode sub-pattern includes the first electrode sub-pattern 211 and the second electrode sub-pattern 210. The first electrode sub-pattern 211 and the second electrode sub-pattern 210 may be formed as an integral structure, and may be formed simultaneously through one patterning process. For example, the first electrode sub-pattern 221, the second electrode sub-pattern 220 and the third electrode sub-pattern 222 of the output electrode sub-pattern may be formed as an integral structure, and may be formed simultaneously through one patterning process.

It should be appreciated that, in order to distinguish the input electrode pattern 21 and the output electrode pattern 22 in a better manner, 211 denotes the first electrode sub-pattern of the input electrode pattern 21 in FIG. 4, and 210 denotes the second electrode sub-pattern of the input electrode pattern 21. 221 denotes the first electrode sub-pattern of the output electrode pattern 22, and 220 denotes the second electrode sub-pattern of the output electrode pattern 22.

As shown in FIGS. 4 and 5, for example, the extension direction of the first electrode sub-pattern 221 is perpendicular to an extension direction of the third electrode sub-pattern 222. The extension direction of the orthographic projection of the second electrode sub-pattern 220 onto the base substrate crosses both an extension direction of the orthographic projection of the first electrode sub-pattern 221 onto the base substrate and an extension direction of an orthographic projection of the third electrode sub-pattern 222 onto the base substrate.

There are various specific structures for the barrier wall structure 23. For example, the barrier wall structure 23 may include a first barrier wall portion 231 extending from the third electrode sub-pattern 222, and the orthographic projection of the first barrier wall portion 231 onto the base substrate is located between the orthographic projections of the two adjacent gate patterns 20 coupled to the same gate line 27 onto the base substrate. In more detail, first barrier wall portions 231 may be set to correspond to the spacers respectively, and the orthographic projection of each first barrier wall portion 231 onto the base substrate is located in the periphery of the orthographic projection of the gate pattern 20 in the transistor structure corresponding to the spacer which corresponds to the first barrier wall portion 231.

As shown in FIGS. 4 and 5, in some embodiments, the barrier wall structure 23 further includes a second barrier wall portion 232 extending from the third electrode sub-pattern 222, an orthographic projection of the third electrode sub-pattern 222 onto the base substrate, the orthographic projection of the first barrier wall portion 231 extending from the third electrode sub-pattern 222 onto the base substrate and an orthographic projection of the second barrier wall portion 232 extending from the third electrode sub-pattern 222 onto the base substrate are all located between orthographic projections of adjacent gate patterns 20 in a same group onto the base substrate, the orthographic projection of the first barrier wall portion 231 onto the base substrate is located between the orthographic projection of the second barrier wall portion 232 onto the base substrate and an orthographic projection of a first gate pattern 20 of the adjacent gate patterns 20 in the same group onto the base substrate, and the orthographic projection of the second barrier wall portion 232 onto the base substrate is located between the orthographic projection of the first barrier wall portion 231 onto the base substrate and an orthographic projection of a second gate pattern of the adjacent gate patterns 20 in the same group onto the base substrate.

To be specific, each gate line 27 is coupled to the gate patterns 20 in the corresponding row of transistor structures. In the row of transistor structures, every two adjacent transistor structures may be divided into a group of transistor structures. The adjacent gate patterns 20 in the same group are two gate patterns 20 in a same group of transistor structures. For example, as shown in FIG. 4, in a same group of transistor structures, a gate pattern 20 in a left transistor structure is the first gate pattern, and a gate pattern 20 in a right transistor structure is the second gate pattern.

When the first barrier wall portion 231 is closer to the first gate pattern, it is able to compensate for a step difference generated by the first gate pattern in a better manner. When the second barrier wall portion 232 is closer to the second gate pattern, it is able to compensate for a step difference generated by the second gate pattern in a better manner. Thus, it is able to improve the stability of the spacer corresponding to the two adjacent gate patterns 20 and reduce the risk of the spacer sliding to the peripheries of the gate patterns.

In some embodiments, second barrier wall portions 231 may be set to correspond to the spacers respectively, and the orthographic projection of each second barrier wall portion 232 onto the base substrate is located in the periphery of the orthographic projection of the gate pattern 20 in the transistor structure corresponding to the spacer which corresponds to the second barrier wall portion 232.

As shown in FIGS. 4 and 5, in some embodiments, the first barrier wall portion 231 includes a first barrier wall pattern 2311 and a second barrier wall pattern 2310 that extend in different directions, the first barrier wall pattern 2311 is coupled to the second barrier wall pattern 2310 at a coupling position where a first angle facing the first gate pattern is formed, and the first angle is less than 180 degrees; and/or, the second barrier wall portion 232 includes a third barrier wall pattern 2321 and a fourth barrier wall pattern 2320 that extend in different directions, the third barrier wall pattern 2321 is coupled to the fourth barrier wall pattern 2320 at a coupling position where a second angle facing the second gate pattern is formed, and the second angle is less than 180 degrees.

To be specific, the first angle and the second angle may be set according to actual needs, and may be the same or different. For example, the first angle and the second angle may each range from 0 degree to 180 degrees. In some embodiments, the first angle and the second angle may each range from 90 degrees to 180 degrees. To be specific, the first angle and the second angle may each be 100 degrees, 110 degrees, 120 degrees, 125 degrees or 130 degrees.

For example, the first barrier wall pattern 2311 and the second barrier wall pattern 2310 are located on a same side of the corresponding gate pattern 20, or, the first barrier wall pattern 2311 is located on a first side of the corresponding gate pattern 20, the second barrier wall pattern 2310 is located on a second side of the corresponding gate pattern 20, and the first side is adjacent to the second side. The first barrier wall pattern 2311 is coupled to the third electrode sub-pattern 212. It should be appreciated that, when the barrier wall structure is used to compensate for the step difference generated by the gate pattern 20, the gate pattern 20 is the gate pattern 20 corresponding to the barrier wall structure.

For example, the third barrier wall pattern 2321 and the fourth barrier wall pattern 2320 are located on a same side of the corresponding gate pattern 20, or, the third barrier wall pattern 2321 is located on a third side of the corresponding gate pattern 20, the fourth barrier wall pattern 2320 is located on a second side of the corresponding gate pattern 20, and the third side is adjacent to the second side. The third barrier wall pattern 2321 is coupled to the third electrode sub-pattern 222.

When the first barrier wall portion 231 and the second barrier wall portion 232 have the above structures, it is able to provide a flat peripheral region of the gate pattern 20, improve the stability of the spacer corresponding to the gate patterns 20 and reduce the sliding risk of the spacer.

In some embodiments, the barrier wall structure 23 is arranged at a same layer and made of a same material as the two electrode patterns.

When the barrier wall structure 23 is arranged at the same layer and made of the same material as the two electrode patterns, the barrier wall structure 23 and the two electrode patterns may be formed simultaneously through one patterning process, so as to simplify a process for forming the array substrate, and reduce manufacture costs.

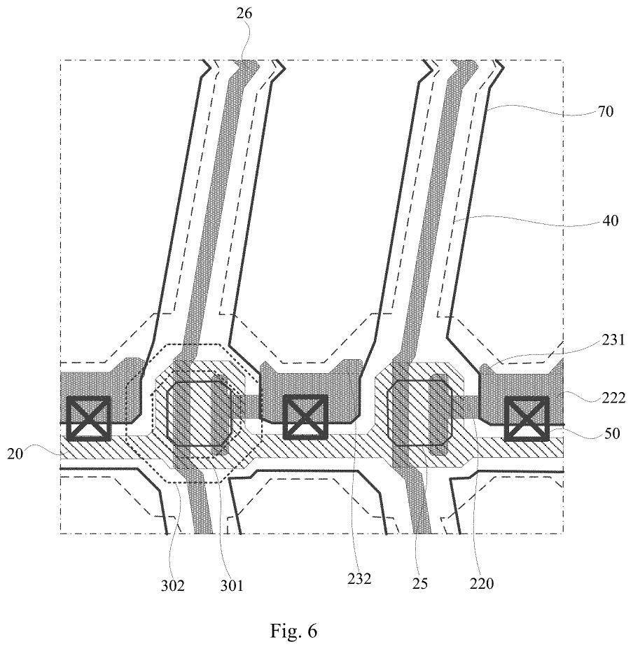

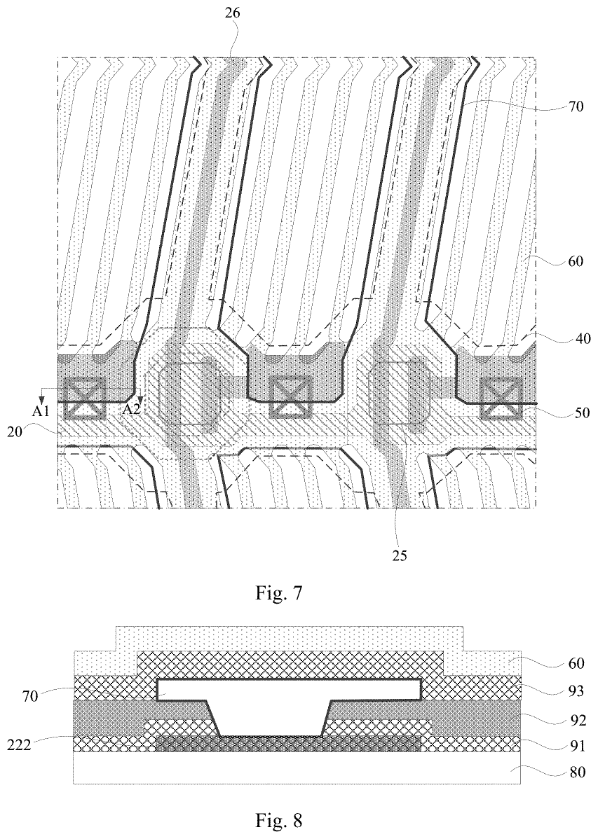

As shown in FIG. 4, FIG. 6 and FIG. 7, in some embodiments, the two electrode patterns include an input electrode pattern 21 and an output electrode pattern 22, the plurality of transistor structures are arranged in an array form, and form a plurality of transistor rows and a plurality of transistor columns. The array substrate further includes a plurality of gate lines 27 and a plurality of data lines 26 crossing each other, the gate lines 27 correspond to the transistor rows respectively, each gate line 27 is coupled to gate patterns 20 of the transistor structures in a corresponding transistor row, the data lines 26 correspond to the transistor columns respectively, and each data line 26 is coupled to second electrode sub-patterns 210 of input electrode patterns 21 of the transistor structures in a corresponding transistor column.

To be specific, the plurality of transistor structures in the array substrate may be arranged in an array form, and form the plurality of transistor rows and the plurality of transistor columns. The plurality of transistor rows are arranged in the Y direction, and each transistor row includes the plurality of transistor structures arranged in the X direction. The plurality of transistor columns are arranged in the X direction, and each transistor column includes the plurality of transistor structures arranged in the Y direction. When the array substrate is applied to a display device, each transistor structure drives a corresponding sub-pixel in the display device to emit light.

The gate lines 27 correspond to the transistor rows respectively, each gate line 27 is coupled to the gate patterns 20 of the transistor structures in the corresponding transistor row, and configured to apply a scan signal to the transistor structures. As shown in FIG. 4, the data lines 26 correspond to the transistor columns respectively, each data line 26 is coupled to the second electrode sub-patterns 210 of the input electrode patterns 21 of the transistor structures in the corresponding transistor column, and configured to apply a data signal to the transistor structures.

For example, each gate line 27 extends in the X direction, and the gate line 27 and the gate patterns 20 coupled to the gate line 27 may be formed as an integral structure. Each data line 26 extends in the Y direction, and the data line 26 and the input electrode patterns 21 coupled to the data line 26 may be formed as an integral structure.

As shown in FIG. 4, for example, the input electrode pattern 21 includes one first electrode sub-pattern 211 and two second electrode sub-patterns 210. Along the extension direction of the data line 26, the two second electrode sub-patterns 210 are located on two opposite sides of the first electrode sub-pattern 211.

For example, the data line 26 includes a plurality of signal transmission portions and a plurality of transistor connection portions that are arranged alternately. Each signal transmission portion is coupled to an adjacent transistor connection portion, and the plurality of the transistor connection portions are further used as the input electrode patterns 21 coupled to the plurality of the transistor connection portions.

In the array substrate of the embodiment of the present disclosure, each data line 26 is coupled to the second electrode sub-pattern 210 of the input electrode pattern 21 in the transistor structure, so as to solve the problem that the data line 26 having a relatively small line width breaks easily at the boundaries of the gate pattern 20 and the active pattern 25 when being coupled to the transistor structure.

It should be appreciated that, as shown in FIGS. 6 and 7, a width of the third electrode sub-pattern 222 in a direction perpendicular to the extension direction thereof is larger than a width of the second electrode sub-pattern 220 in a direction perpendicular to the extension direction thereof. The first barrier wall portion 231 in the barrier wall structure is formed as a triangle-like protrusion structure, the second barrier wall portion 232 in the barrier wall structure is formed as a protrusion structure, and an angle is formed between the protrusion structure and the third electrode sub-pattern 222.

A display device is further provided, including the above-mentioned array substrate.

In the array substrate of the embodiments of the present disclosure, the second electrode sub-pattern 210 covers a part of the first boundary of the gate pattern 20, and the angle between the extension direction of the orthographic projection of the second electrode sub-pattern 210 onto the base substrate and the extension direction of the orthographic projection of the part of the first boundary onto the base substrate is less than 90 degrees. Thus, the second electrode sub-pattern 210 may obliquely climb the step generated by the gate pattern 20 at the part of the first boundary, so as to change a step angle of the second electrode sub-pattern 210, and increase the step width of the second electrode sub-pattern 210 without increasing the width of the second electrode sub-pattern 210 in the direction perpendicular to the extension direction thereof, thereby to reduce the probability of the second electrode sub-pattern 210 breaking at the step while avoiding such problems as the decrease of the charging rate of the transistor and the increase of the logic power consumption. In addition, the array substrate of the embodiments of the present disclosure may be applied to the high-resolution display product.

Therefore, when the display device in the embodiment of the present disclosure includes the above-mentioned array substrate, the above-mentioned beneficial effects may also be achieved, which will not be particularly defined herein.

It should be appreciated that the display device may specifically include an organic light-emitting diode display device and a liquid crystal display device. A size and resolution of the display device may be set according to actual needs. For example, the display device includes a B8 13.3-inch Full High Definition (FHD) display device.

In some embodiments, the display device further includes a color filter substrate disposed opposite to the array substrate, the color filter substrate includes a plurality of spacers corresponding to at least part of gate patterns 20 in the array substrate respectively, an orthographic projection (as shown by 301) of a top surface of each spacer close to the array substrate onto the base substrate of the array substrate overlaps an orthographic projection of the corresponding gate pattern 20 onto the base substrate, and an orthographic projection of a barrier wall structure 23 in the periphery of the gate pattern 20 onto the base substrate is located at the periphery of the orthographic projection of the top surface of each spacer close to the array substrate onto the base substrate.

To be specific, the spacer may be formed on the color filter substrate, and there are various specific shapes for the spacer. For example, the spacer has a columnar structure, a cross section of the spacer in a direction perpendicular to the array substrate is of a trapezoidal shape, an area of a bottom surface of the spacer close to the color filter substrate is larger than an area of the top surface of the spacer close to the array substrate, and the top surface and the bottom surface are each of a circular shape, a hexagon shape, an octagon shape, etc. It should be appreciated that, 302 in FIG. 6 denotes an orthographic projection of the bottom surface onto the base substrate.

When the orthographic projection of the top surface of the spacer close to the array substrate onto the base substrate of the array substrate overlaps the orthographic projection of the corresponding gate pattern 20 onto the base substrate, and the orthographic projection of the barrier wall structure 23 in the periphery of the gate pattern 20 onto the base substrate is located at the periphery of the orthographic projection of the top surface of the spacer close to the array substrate onto the base substrate, it is able to provide a relatively flat surface of the transistor structure in the array substrate away from the base substrate, so as to reduce the sliding probability of a top end of the spacer away from the color filter substrate, and improve the stability of the spacer in a better manner.

As shown in FIGS. 6 and 7, in some embodiments, the color filter substrate may further include a black matrix layer, and an orthographic projection (as shown by 401) of the black matrix layer onto the base substrate of the array substrate covers the orthographic projection of the barrier wall structure 23 in the array substrate onto the base substrate.

To be specific, the color filter substrate may further be provided with the black matrix layer used to shield the transistor structures on the array substrate.

When the orthographic projection of the black matrix layer onto the base substrate of the array substrate covers the orthographic projection of the barrier wall structure 23 in the array substrate onto the base substrate, so that the barrier wall structure 23 may also be shielded by the black matrix layer, thereby to prevent the pixel aperture ratio of the display device from being affected adversely by the barrier structure 23, and guarantee that the display device has a higher pixel aperture ratio.

In the display device of the above embodiments, it is able to increase a yield rate of the array substrate to 99% while no defects such as sliding of the spacer occur on the basis of a high pixel transmittance (such as 8.2%).

It should be appreciated that, in FIGS. 6 to 8, FIG. 8 is a sectional view of the array substrate in FIG. 7 along line A1A2. A pixel electrode pattern 70 is coupled to the third electrode sub-pattern 222 of the output electrode pattern 22 in the corresponding transistor structure through a corresponding connection hole 50, and receives a driving signal transmitted by the third electrode sub-pattern 222. Other film layers are further included between the base substrate 80 and the third electrode sub-pattern 222, which are not shown in the figures. A first passivation layer 91 and a planarization layer 92 are included between the third electrode sub-pattern 222 and the pixel electrode pattern 70, and the connection hole 50 penetrates the first passivation layer 91 and the planarization layer 92. A second passivation layer 93 and a common electrode layer 60 are further provided on a side of the pixel electrode pattern 70 away from the base substrate 80.

A method for forming the above-mentioned array substrate is provided, including: forming a plurality of transistor structures arranged on a base substrate. Each transistor structure includes: a gate pattern 20, an active pattern 25 located on a side of the gate pattern 20 away from the base substrate, the active pattern 25 including two electrode contact regions spaced apart from each other and a channel region located between the two electrode contact regions; and two electrode patterns located on a side of the active pattern 25 away from the base substrate and corresponding to the two electrode contact regions respectively. Each electrode pattern includes a first electrode sub-pattern 211 and a second electrode sub-pattern 210 coupled to each other, an orthographic projection of the first electrode sub-pattern 211 onto the base substrate and an orthographic projection of a corresponding electrode contact region onto the base substrate form a first overlapping region, the first electrode sub-pattern 211 is coupled to the active pattern located in the corresponding electrode contact region in the first overlapping region, the second electrode sub-pattern 210 covers a part of a first boundary of the gate pattern 20, and an angle between an extension direction of an orthographic projection of the second electrode sub-pattern 210 onto the base substrate and an extension direction of an orthographic projection of the part of the first boundary onto the base substrate is less than 90 degrees.

To be specific, the array substrate includes a first gate metal layer, an insulation layer, an active layer, an insulation layer and a source-drain metal layer that are sequentially laminated one on another in a direction away from the base substrate. The gate pattern 20 in the transistor structure may be formed by using the first gate metal layer, the active pattern 25 may be formed by using the active layer, the two electrode patterns may be formed by using the source-drain metal layer, and the transistor structure may be formed as a thin film transistor having a bottom gate structure.

The active pattern 25 has various layout modes. For example, an orthographic projection of the active pattern 25 onto the base substrate is within an orthographic projection of the gate pattern 20 onto the base substrate. Further, the active pattern 25 includes the two electrode contact regions spaced apart from each other and the channel region located between the two electrode contact regions. The channel region may be specifically I-shaped, L-shaped, U-shaped or another shape.

The two electrode patterns may be used as an input electrode pattern 21 and an output electrode pattern 22 respectively of the transistor structure, and correspond to the two electrode contact regions respectively. Each electrode pattern includes the first electrode sub-pattern 211 and the second electrode sub-pattern 210 coupled to each other, the orthographic projection of the first electrode sub-pattern 211 onto the base substrate and the orthographic projection of the corresponding electrode contact region onto the base substrate form a first overlapping region, a via-hole may be provided in the first overlapping region, and the first electrode sub-pattern 211 is coupled to the active pattern in the corresponding electrode contact region through the via-hole. Further, the orthographic projection of the first electrode sub-pattern 211 onto the base substrate may be, but not limited to, within the orthographic projection of the corresponding electrode contact region onto the base substrate.

There are various specific structures for the second electrode sub-pattern 210. For example, in a direction parallel to the base substrate, the second electrode sub-pattern 210 may extend from the periphery of the gate pattern 20 to the corresponding electrode contact region, and be coupled to the first electrode sub-pattern 211. The second electrode sub-pattern 210 may cover a part of the first boundary of the gate pattern 20, that is, the second electrode sub-pattern 210 extends across a step generated by the gate pattern 20 at the part of the first boundary.

As shown in FIG. 3, when the angle a1 between the extension direction of the orthographic projection of the second electrode sub-pattern 210 onto the base substrate and the extension direction of the orthographic projection of the part of the first boundary onto the base substrate is less than 90 degrees, it is able to increase a step width of the second electrode sub-pattern 210 at the part of the first boundary. It should be appreciated that, the step width is referred to as a width of a step portion of the second electrode sub-pattern 210 at the part of the first boundary along an extension direction of the part of the first boundary.

For example, as shown in FIGS. 2 and 3, the step width of the second electrode sub-pattern 210 is 4 μm, and a width of the second electrode sub-pattern 210 in a direction perpendicular to an extension direction thereof is 3 μm. Further, when a1 is 45 degrees, the step width of the second electrode sub-pattern 210 may reach 4.25 μm. Therefore, when setting the second electrode sub-pattern 210 by using the above-mentioned mode, it is able to avoid the increase of the overlapping capacitance between the second electrode sub-pattern 210 and the gate pattern 20 while increasing the step width.

In the array substrate formed by using the method in the embodiments of the present disclosure, the second electrode sub-pattern 210 covers a part of the first boundary of the gate pattern 20, and the angle between the extension direction of the orthographic projection of the second electrode sub-pattern 210 onto the base substrate and the extension direction of the orthographic projection of the part of the first boundary onto the base substrate is less than 90 degrees. Thus, the second electrode sub-pattern 210 may obliquely climb the step generated by the gate pattern 20 at the part of the first boundary, so as to change a step angle of the second electrode sub-pattern 210, and increase the step width of the second electrode sub-pattern 210 without increasing the width of the second electrode sub-pattern 210 in the direction perpendicular to the extension direction thereof, thereby to reduce the probability of the second electrode sub-pattern 210 breaking at the step while avoiding such problems as the decrease of the charging rate of the transistor and the increase of the logic power consumption. In addition, the array substrate formed by using the method in the embodiments of the present disclosure may be applied to the high-resolution display product.

In some embodiments, the forming the two electrode patterns includes: forming a first electrode sub-pattern 211 and a second electrode sub-pattern 210 in each electrode pattern and a barrier wall structure 23 in the array substrate simultaneously through one patterning process.

To be specific, when the first electrode sub-pattern 211 and the second electrode sub-pattern 210 in each electrode pattern is arranged at a same layer and made of a same material as the barrier wall structure 23 in the array substrate, the first electrode sub-pattern 211 and the second electrode sub-pattern 210 in each electrode pattern and the barrier wall structure 23 in the array substrate may be formed simultaneously through one patterning process, so as to simplify a process for forming the array substrate, and reduce manufacture costs.

It should be appreciated that, the above embodiments have been described in a progressive manner, and the same or similar contents in the embodiments have not been repeated, i.e., each embodiment has merely focused on the difference from the others. Especially, the product embodiments are substantially similar to the method embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are merely for illustrative purposes, but shall not be construed as limiting the scope of the present disclosure. Any modifications or replacements that would easily occurred to a person skilled in the art, without departing from the technical scope disclosed in the disclosure, should be encompassed in the protection scope of the present disclosure. Therefore, the scope of the present disclosure shall be subject to the scope defined by the appended claims.

1. An array substrate, comprising: a base substrate and a plurality of transistor structures arranged on the base substrate, wherein each transistor structure comprises:
a gate pattern,
an active pattern located on a side of the gate pattern away from the base substrate, the active pattern comprising two electrode contact regions spaced apart from each other and a channel region located between the two electrode contact regions; and
two electrode patterns located on a side of the active pattern away from the base substrate and corresponding to the two electrode contact regions respectively, wherein each electrode pattern comprises a first electrode sub-pattern and a second electrode sub-pattern coupled to each other, an orthographic projection of the first electrode sub-pattern onto the base substrate and an orthographic projection of a corresponding electrode contact region onto the base substrate form a first overlapping region, the first electrode sub-pattern is coupled to the active pattern located in the corresponding electrode contact region in the first overlapping region, the second electrode sub-pattern covers a part of a first boundary of the gate pattern, and an angle between an extension direction of an orthographic projection of the second electrode sub-pattern onto the base substrate and an extension direction of an orthographic projection of the part of the first boundary onto the base substrate is less than 90 degrees.

2. The array substrate according to claim 1, wherein an orthographic projection of the active pattern onto the base substrate is covered by an orthographic projection of the gate pattern onto the base substrate, the second electrode sub-pattern covers a part of a second boundary of the active pattern, and an angle between the extension direction of the orthographic projection of the second electrode sub-pattern onto the base substrate and an extension direction of an orthographic projection of the part of the second boundary onto the base substrate is less than 90 degrees.

3. The array substrate according to claim 1, further comprising: a plurality of gate lines, a plurality of transistors forming a plurality of transistor rows arranged sequentially along a first direction, each transistor row comprising the plurality of the transistor structures spaced apart from each other along a second direction, the gate lines corresponding to the transistor rows respectively, and each gate line being coupled to gate patterns of the transistor structures in a corresponding transistor row; and
a barrier wall structure, an orthographic projection of at least a part of the barrier wall structure onto the base substrate being located between orthographic projections of two adjacent gate patterns coupled to a same gate line onto the base substrate.

4. The array substrate according to claim 3, wherein an orthographic projection of each gate pattern onto the base substrate is located between orthographic projections of two adjacent barrier wall structures onto the base substrate.

5. The array substrate according to claim 3, wherein the two electrode patterns comprise an input electrode pattern and an output electrode pattern, the output electrode pattern comprises the first electrode sub-pattern, the second electrode sub-pattern and a third electrode sub-pattern coupled to each other sequentially, the second electrode sub-pattern is located between the first electrode sub-pattern and the third electrode sub-pattern, and in the transistor structure where the third electrode sub-pattern is located, the third electrode sub-pattern is located on a side of the first electrode sub-pattern away from the input electrode pattern; and
the barrier wall structure comprises a first barrier wall portion extending from the third electrode sub-pattern, and an orthographic projection of the first barrier wall portion onto the base substrate is located between the orthographic projections of the two adjacent gate patterns coupled to the same gate line onto the base substrate.

6. The array substrate according to claim 5, wherein the barrier wall structure further comprises a second barrier wall portion extending from the third electrode sub-pattern, an orthographic projection of the third electrode sub-pattern onto the base substrate, the orthographic projection of the first barrier wall portion extending from the third electrode sub-pattern onto the base substrate and an orthographic projection of the second barrier wall portion extending from the third electrode sub-pattern onto the base substrate are all located between orthographic projections of adjacent gate patterns in a same group onto the base substrate, the orthographic projection of the first barrier wall portion onto the base substrate is located between the orthographic projection of the second barrier wall portion onto the base substrate and an orthographic projection of a first gate pattern of the adjacent gate patterns in the same group onto the base substrate, and the orthographic projection of the second barrier wall portion onto the base substrate is located between the orthographic projection of the first barrier wall portion onto the base substrate and an orthographic projection of a second gate pattern of the adjacent gate patterns in the same group onto the base substrate.

7. The array substrate according to claim 6, wherein the first barrier wall portion comprises a first barrier wall pattern and a second barrier wall pattern that extend in different directions, the first barrier wall pattern is coupled to the second barrier wall pattern at a coupling position where a first angle facing the first gate pattern is formed, and the first angle is less than 180 degrees;
and/or, the second barrier wall portion comprises a third barrier wall pattern and a fourth barrier wall pattern that extend in different directions, the third barrier wall pattern is coupled to the fourth barrier wall pattern at a coupling position where a second angle facing the second gate pattern is formed, and the second angle is less than 180 degrees.

8. The array substrate according to claim 3, wherein the barrier wall structure is arranged at a same layer and made of a same material as the two electrode patterns.

9. The array substrate according to claim 1, wherein the two electrode patterns comprise an input electrode pattern and an output electrode pattern; the plurality of transistor structures are arranged in an array form, and form a plurality of transistor rows and a plurality of transistor columns; the array substrate further comprises a plurality of gate lines and a plurality of data lines crossing each other, the gate lines correspond to the transistor rows respectively, each gate line is coupled to gate patterns of the transistor structures in a corresponding transistor row, the data lines correspond to the transistor columns respectively, and each data line is coupled to second electrode sub-patterns of input electrode patterns of the transistor structures in a corresponding transistor column.

10. A display device, comprising the array substrate according to claim 1.

11. The display device according to claim 10, further comprising a color filter substrate disposed opposite to the array substrate, wherein the color filter substrate comprises a plurality of spacers corresponding to at least part of gate patterns in the array substrate respectively, an orthographic projection of a top surface of each spacer close to the array substrate onto the base substrate of the array substrate overlaps an orthographic projection of the corresponding gate pattern onto the base substrate, and an orthographic projection of a barrier wall structure in the array substrate onto the base substrate is located at the periphery of the orthographic projection of the top surface onto the base substrate.

12. The display device according to claim 10, further comprising a color filter substrate disposed opposite to the array substrate, wherein the color filter substrate comprises a black matrix layer, and an orthographic projection of the black matrix layer onto the base substrate of the array substrate covers an orthographic projection of a barrier wall structure in the array substrate onto the base substrate.

13. A method for forming the array substrate according to claim 1, comprising:
forming a plurality of transistor structures arranged on a base substrate, wherein each transistor structure comprises: a gate pattern, an active pattern located on a side of the gate pattern away from the base substrate, the active pattern comprising two electrode contact regions spaced apart from each other and a channel region located between the two electrode contact regions; and two electrode patterns located on a side of the active pattern away from the base substrate and corresponding to the two electrode contact regions respectively, wherein each electrode pattern comprises a first electrode sub-pattern and a second electrode sub-pattern coupled to each other, an orthographic projection of the first electrode sub-pattern onto the base substrate and an orthographic projection of a corresponding electrode contact region onto the base substrate form a first overlapping region, the first electrode sub-pattern is coupled to the active pattern located in the corresponding electrode contact region in the first overlapping region, the second electrode sub-pattern covers a part of a first boundary of the gate pattern, and an angle between an extension direction of an orthographic projection of the second electrode sub-pattern onto the base substrate and an extension direction of an orthographic projection of the part of the first boundary onto the base substrate is less than 90 degrees

14. The method for forming the array substrate according to claim 13, wherein the forming the two electrode patterns comprises: forming a first electrode sub-pattern and a second electrode sub-pattern in each electrode pattern and a barrier wall structure in the array substrate simultaneously through one patterning process.
